(19) United States
(12) Patent Application Publication
(10) Pub. No.: US 2006/0001114 A1
(43) Pub. Date: Jan. 5, 2006

(54) Apparatus and method of wafer level package

(76) Inventors: Jen-Yi Chen, Hsin-Chu (TW); Jing-Hung Chiou, Taipei (TW); Kai-Hsiang Yen, Taipei City (TW)

Correspondence Address: BIRCH STEWART KOLASCH & BIRCH, PO BOX 747, FALLS CHURCH, VA, 22040-0747, US

(21) Appl. No.: 10/927,066

(22) Filed: Aug. 27, 2004

(30) Foreign Application Priority Data
Jun. 30, 2004 (TW) 093119660

(51) Int. Cl. H01L 29/82

(52) U.S. Cl. 257/415

(57) ABSTRACT

An apparatus of wafer level package for the micro elements and methods of fabricating the same is disclosed. The apparatus is utilized to provide a lid substrate for bonding the lid substrate to a substrate having several micro elements and therefore form a cavity capable of being operated for the micro elements. The openings of the cavity are used to make the micro elements capable of being contacted with the atmosphere and therefore form an apparatus of wafer level package for the micro elements.

### BACKGROUND OF THE INVENTION

1. Field of the Invention

The present invention generally relates to wafer level package, and more particularly to a wafer level package method of fabricating a cavity capable of being operated for micro elements and several openings capable of being contacted with atmosphere for micro elements, and to a package apparatus of fabricating the same.

2. Description of the Prior Art

The purposes and the advantages of wafer level package includes decreasing the production cost, decreasing the effect caused by the parasitic capacitance and parasitic inductance by using shorter conductive line path, acquiring better SNR (i.e. signal to noise ratio). Furthermore, the size of a wafer-level package product is close to the size of a chip, it is therefore that the size of the chip determines the package volume and it corresponds to the minimization trend of micro sensors.

In some prior techniques relevant to the present invention, the process includes the steps of aligning a lid substrate and a substrate, and bonding of them in a cavity; penetrating the lid substrate for forming a signal fetch window. In addition, according to the results of the chips finished the dicing step, since the signal legs positioned in the chip edge are not blocked by the upper chips, thus they can be connected to outward circuits by a wire-bonding method. The problem is that, the step of penetrating the lid substrate is needed after the wafers are bonded, the risk in package process will be increased. Besides, when the element under a package process is a MEMS (micro-electro-mechanical systems) element, there are adhesive materials around the micro structure, thus a bonding step of the lid substrate and the substrate is performed after an aligning step; then, the lid substrate and the substrate is bonded, the signal pad windows and openings are open by a cut-off step or an etching method. The problem is that, however, the height of being operated by the micro elements (after the bonding step) is limited according to the adhesive material, the ring-shaped adhesive material of micro elements should be insulated with the conductive lines positioned in the chip edges, therefore the complexity of the package process is increased. Further, the lead of signals is limited to wire-bonding, and they might be collided with the wire-bonding mouth of the wire-bonding machine, it is therefore that only the preceding process corresponds with the basic concepts of the wafer level package, while the later process still uses the conventional single-chip processing method.

Besides, another prior technique relevant to the present invention, the process includes the steps of generating a shallow notch and the signal window penetrating to the wafer, aligning a lid substrate and a substrate and bonding of them. Thus, the shallow notch will form a cavity capable of being operated by the micro elements, and the window penetrating to the lid substrate becomes the position of leading the signals. Next, by using a stopping-off method to fill the signal window with Pb—Sn solder for being applied to the adhesive filling step. The problem is that the step of penetrating the lid substrate is needed to precede with the process, however, the penetrating process is expensive and needs a processing step of insulation. When the ring-shaped adhesive material of micro elements are solder bumps, the complexity of the processing step of insulation will be increased; when the bonding step of wafers uses glass as a medium, anodic bonding method is used and it needs a high-temperature (400° C.), thus the usage is limited to the temperature.

To solve the above-mentioned problems, another prior technique relative to the present invention, the process includes the steps of dispensing the protective gel on the micro sensors, dicing the wafer into several chips, performing a plastic package by using the EMC (epoxy molding compound) method, revealing the protective gel by a borer used on the plastic substrate, and removing the protective gel for allowing the micro sensors to be in contact with the atmosphere. The problem is that, it is difficult when aligning the borer on the plastic substrate, it is a very careful process when avoiding damage when the borer step is performed; the package step is performed after the dicing step of the wafer, thus the cost is higher when there are large-amounts of production; the volume of the packaged product is lager than the size of chips, thus it is unfavorable to the cost control of micro sensors.

### SUMMARY OF THE INVENTION

As is described above, the problems of techniques in the prior art are limited in applications; thus, one of the purposes of the present invention is to provide a wafer level package method capable of lot production and an apparatus of fabricating the same.

Another one of the purposes of the present invention is to provide the wafer level package method for avoiding the elements from some damage by external mechanics during the package process.

Still another one of the purposes of the present invention is to provide a wafer level package, including some advantages: a masking process is not needed after the bonding process, high-temperature process can be avoided, harmony with a flip-chip package by using the solder bump implantation method.

Accordingly, the present invention provides an apparatus of wafer level package for the micro elements and methods of fabricating the same. The apparatus is utilized to provide a lid substrate for bonding to a substrate having several micro elements and therefore form a cavity for operating of the micro elements. The openings of the cavity are used to make the micro elements be in contact with the atmosphere and therefore form an apparatus of wafer level package for the micro elements.

### BRIEF DESCRIPTION OF THE DRAWINGS

The present invention can be best understood through the following description and accompanying drawings, wherein:

FIG. 1A˜FIG. 1D are the diagrams illustrating the steps of forming a lid substrate by the thermoforming method;

FIG. 2A˜FIG. 2C are the diagrams illustrating the steps of forming a lid substrate by the etching method;

FIG. 3A˜FIG. 3F are the diagrams illustrating the wafer level package process according to one embodiment of the present invention;

FIG. 4A˜FIG. 4F are the diagrams illustrating the wafer level package process harmony with a flip-chip package according to another embodiment of the present invention;

FIG. 5A˜FIG. 5D are the diagrams illustrating the wafer level package process according to still another embodiment of the present invention; and

FIG. 6A˜FIG. 6D are the diagrams illustrating the wafer level package process according to still another embodiment of the present invention.

### DESCRIPTION OF THE PREFERRED EMBODIMENT

Some appropriate and preferred embodiments of the present invention will now be described in the following. It should be noted, however, that the embodiment is merely an example and can be variously modified without departing from the range of the present invention.

The wafer level package apparatus of the present invention is utilized to provide a lid substrate having several notches and openings for bonding to a substrate having several micro elements and therefore form a cavity for operating the micro elements (for instance, micro inertial sensors, micro pressure gauge, micro hygrometer and micro gas sensors). Further, the openings of the cavity are used to make the micro elements to be contacted with the atmosphere. The structure of the apparatus includes a substrate and a lid substrate, where the substrate has several elements and several pads that are corresponding to the elements, and the lid substrate has several openings and notches configured to correspond to the elements and the pads of the substrate. Accordingly, it forms a wafer level package structure after the bonding of the substrate and the lid substrate is finished. Furthermore, the wafer level package structure of the present invention includes two structures, one is bonding with adhesive and another one is bonding without adhesive; where the method of bonding with adhesive is to dispense the lid substrate with adhesive for bonding to the substrate, and the method of bonding without adhesive is to combine the substrate with the lid substrate by anodic bonding.

It should be noted that the material of the substrate according to the embodiments of the present invention is not limited to a silicon wafer; while the material can be ceramics, high polymeric aminates, silicon wafer, glass, compounds and plastics in practical applications, and which the kind of material chosen depends on the process requirement. For instance, the material of the substrate can be glass or plastics when there is no high-temperature process during the package process (i.e. lower than 400° C.); while the material of the substrate can be ceramics, high polymeric aminates, compounds when there is a high-temperature process during the package process (i.e. greater than 400° C.). Similarly, the material of the lid substrate according to the embodiments of the present invention is not limited to a silicon wafer; which the kind of material chosen depends on the process requirement too. For instance, the material of the lid substrate is selected from the group consisting of thermoplastic polyester, polycarbonate (PET) and PC when using the thermoforming method; the material of the lid substrate is selected from the group consisting of silicon wafer and glass when using the etching method; the material of the lid substrate is epoxy when using the EMC (epoxy molding compound) method. As regards to the details of the wafer level package process according to the present invention, they will be described in the following.

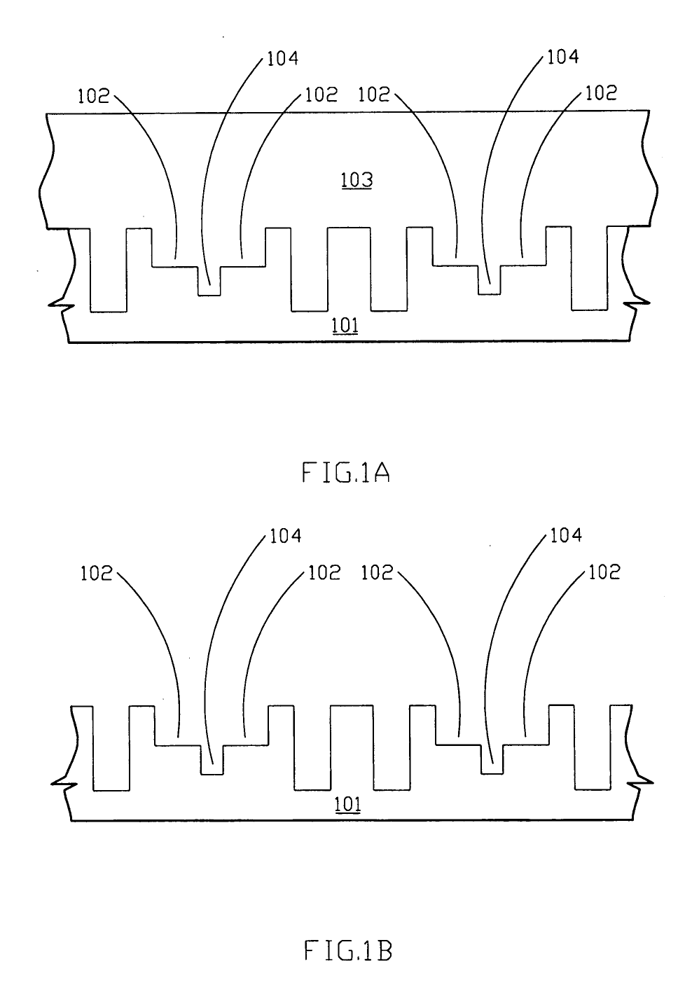

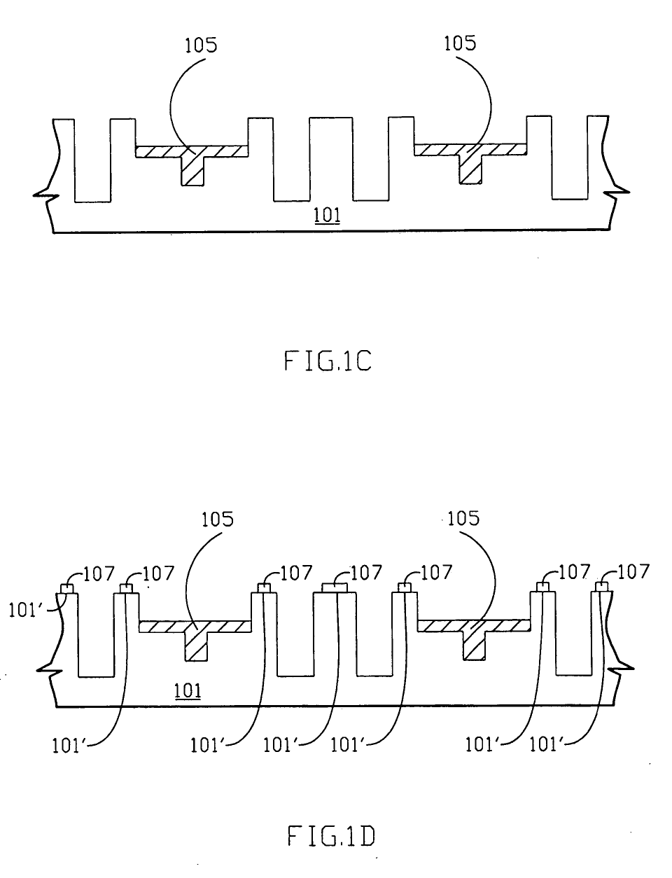

According to the above-mentioned description, in the embodiments of the present invention, the method of fabricating the lid substrate can be a thermoforming method, an etching method and an EMC (epoxy molding compound) method. First, referring to FIG. 1A˜FIG. 1C, the diagrams depict the steps of forming a lid substrate by the thermoforming method. The steps includes, combining a lid substrate 101 with a mold 103 having predetermined forms (as shown in FIG. 1A); generating the notches 102 and the openings 104 onto the lid substrate 101 by using a thermoforming method; parting the lid substrate 101 having the notches 102 and the openings 104 from the mold 103 (as shown in FIG. 1B); filling the notches 102 and the opening 104 with a protective gel 105 for closing the notches 102 and the openings 104 (as shown in FIG. 1C). In the embodiment, the material of the lid substrate 101 can be thermoplastic polyester, polycarbonate (PET) and PC, and the protective gel 105 can be a soluble material, for instance, photoresist, polyimide and benzocyclobutene (BCB). Besides, after the fabricating process of lid substrate is finished, it can further include a step of dispensing the upper edge 101′ of the lid substrate with an adhesive 101 according to the material of the substrate (as shown in FIG. 1D); and the material of the adhesive 101 is not restricted in the embodiments of the present invention. It should be emphasized herein that the diagrams of FIG. 1A˜FIG. 1D can also depict the steps of forming a lid substrate by the EMC method, where the material of the lid substrate 101 can be epoxy resin.

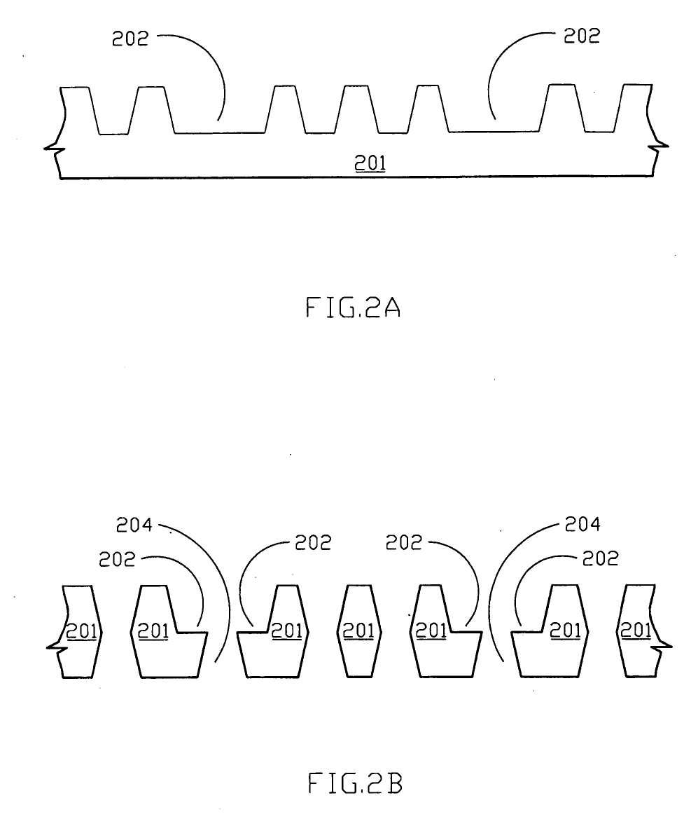

In the following, referring to FIG. 2A˜FIG. 2C, the diagrams depict the steps of forming a lid substrate by the etching method. The steps include, etching the top side of a lid substrate 201 with some appropriate patterns for forming the notches 202 (as shown in FIG. 2A); etching the back side of the lid substrate 201 with some appropriate patterns for forming the openings 204 (as shown in FIG. 2B); filling the notches 202 and the opening 204 with a protective gel 203 for closing the notches 202 and the openings 204 and forming a lid substrate 201 (as shown in FIG. 2C). In the embodiment, the material of the lid substrate 201 can be silicon wafer or glass, and the protective gel 203 can be a soluble material, for instance, photoresist, polyimide and benzocyclobutene (BCB). Besides, after the fabricating process of the lid substrate is finished, it can further includes a step of dispensing the upper edge of the lid substrate 201 with an adhesive according to the material of substrate (which is not shown in the figures); and the material of the adhesive is not restricted in the embodiments of the present invention.

As is described above, after the several notches (102 and 202) and the several openings (104 and 204) of the lid substrate (101 and 201) are generated in accordance with the micro elements and the pads of the substrate, then performing a bonding process for forming a wafer level package structure. Further, the details of the bonding process will be described in the following.

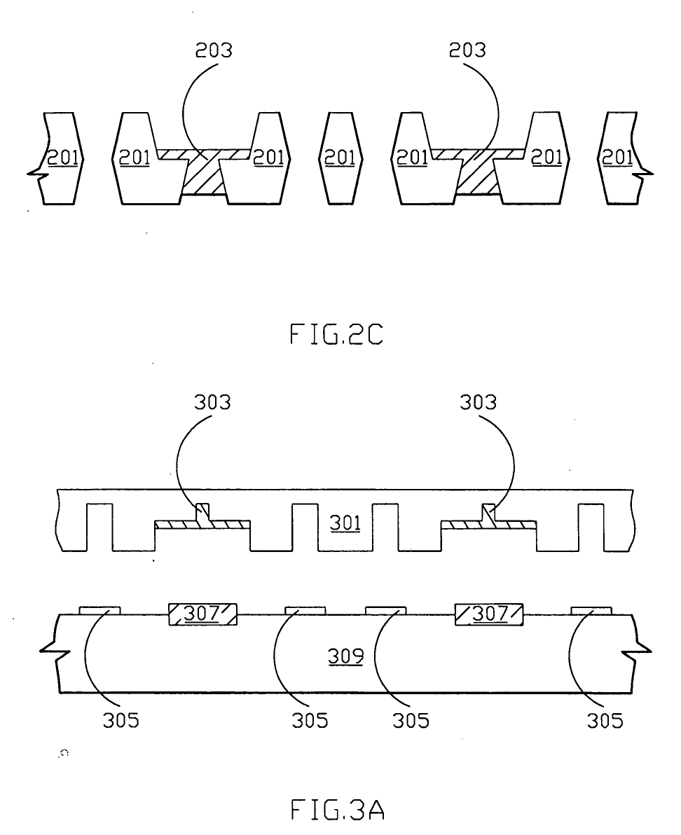

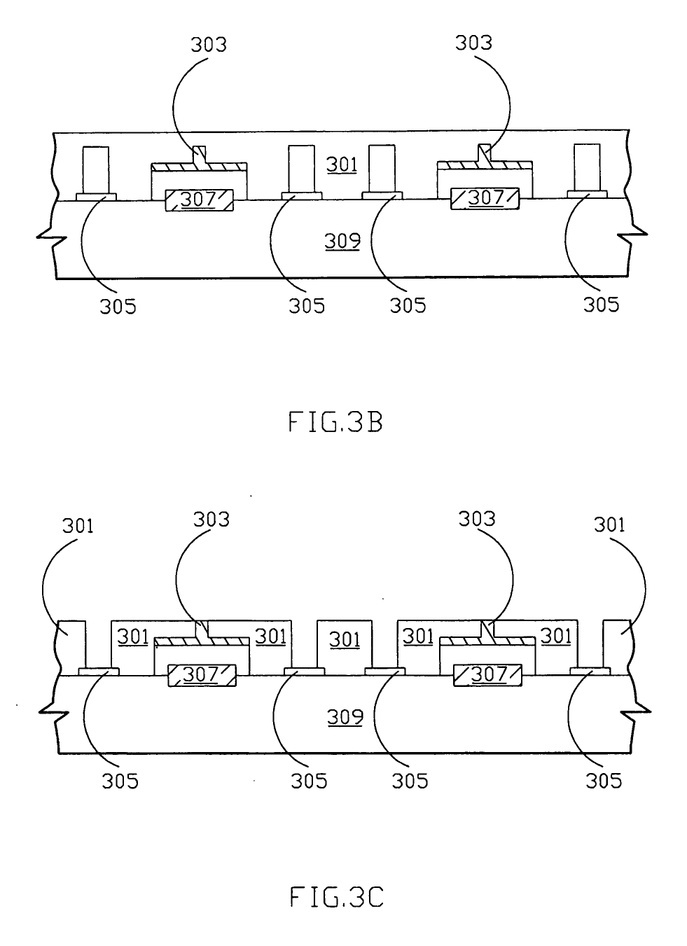

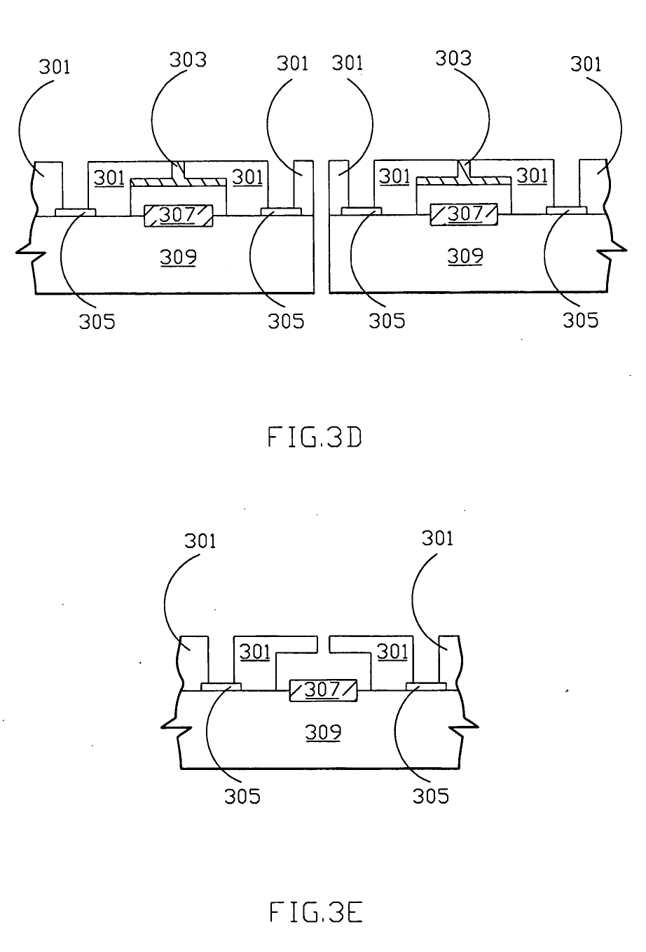

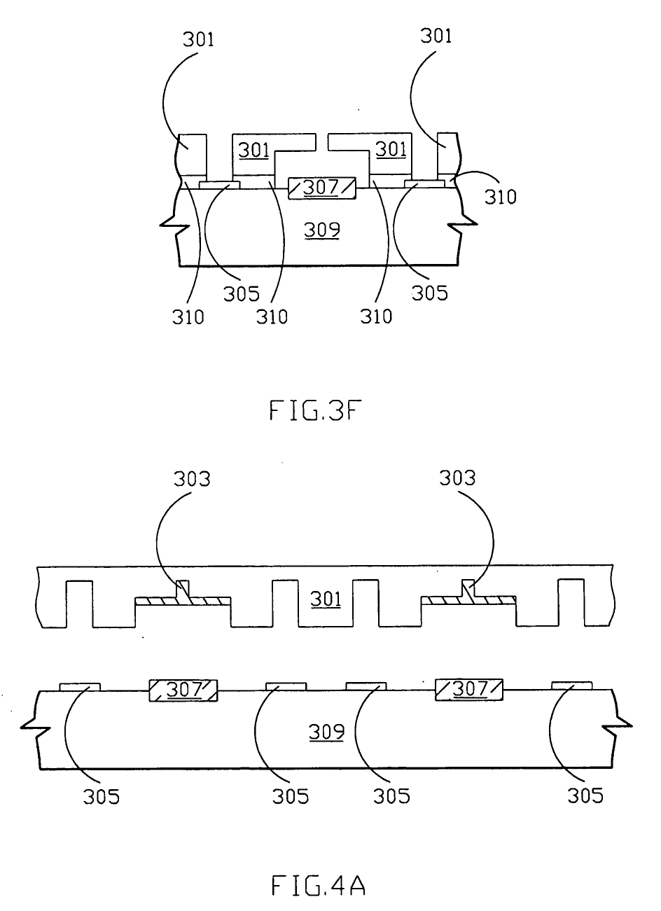

FIG. 3A˜FIG. 3F are the diagrams illustrating the wafer level package process according to one embodiment of the present invention, which includes the steps of aligning the substrate 309 and the lid substrate 301 (as shown in FIG. 3A), where the lid substrate 301 is formed by a thermoforming method, an etching method and an EMC method, and the lid substrate 301 has several notches and openings filled with a protective gel 303; bonding the lid substrate 301 to the substrate 309 (as shown in FIG. 3B), where the substrate 309 includes several elements 307, for instance, micro inertial sensors, micro pressure gauge, micro hygrometer and micro gas sensors. After the bonding of the lid substrate 301 and substrate 309, there is a cavity (toward to the elements 307) on the lid substrate which is formed, it is used to form a space for operating of the elements 307. Besides, the other notches (without openings) on the lid substrate 301 are toward the pads 309 of the elements 307. It should be appreciated that, since the notches and the openings are closed by the protective gel 303, thus the elements 307 becomes in a seal situation after bonding of the lid substrate 301 and substrate 309. Then, by using a lapping process, lapping the lid substrate 301 (as shown in FIG. 3C) and revealing the protective gel 303 and the pads 305. And next, a dicing step is performed for making each of the elements 307 of the substrate 309 diced in a single chip. Since the protective gel 303 closes the notches and the openings, thus the cuttings and trimmings will not be in contact with the elements during the lapping process, as shown in FIG. 3D. Next, removing the protective gel 303 by an appropriate method and then making the elements be in contact with the atmosphere (for instance, by using organic solution or reactive gas). Finally, by using a wire-bonding method, making them connected the external circuit with the pads of the elements.

It should be appreciated that, during the bonding process of the embodiments, the bonding method has different ways in accordance with the materials of the substrate 309 and the lid substrate 301. The substrate and lid substrate can be combined by anodic bonding when the material of the substrate is a silicon wafer and the material of the lid substrate is glass or when the material of the substrate is glass and the material of the lid substrate is a silicon wafer. Further, the combined structure of the package is as shown in FIG. 3E. When the material of the substrate 309 or the material of the lid substrate 301 is selected from the material except for the silicon wafer (or glass), for instance, the material of the substrate 309 is a silicon wafer and the lid substrate 301 is formed by the thermoforming method, it is needed as a dispensing process for dispensing the upper edge of the lid substrate 301 with an adhesive 310 and combining of the substrate 309 with the lid substrate 301. It should be noted that the dispensing process used in the embodiments of the present invention is not limited in dispensing; it can further be a screen printing, photolighography and a definable UV gel. Furthermore, the combined structure of the package is as shown in FIG. 3F. In addition, the protective gel in the embodiments according to the present invention can be photoresist, polyimide and benzocyclobutene (BCB). The lapping process in the embodiments according to the present invention can be an etching method, a grinding method and a polishing method.

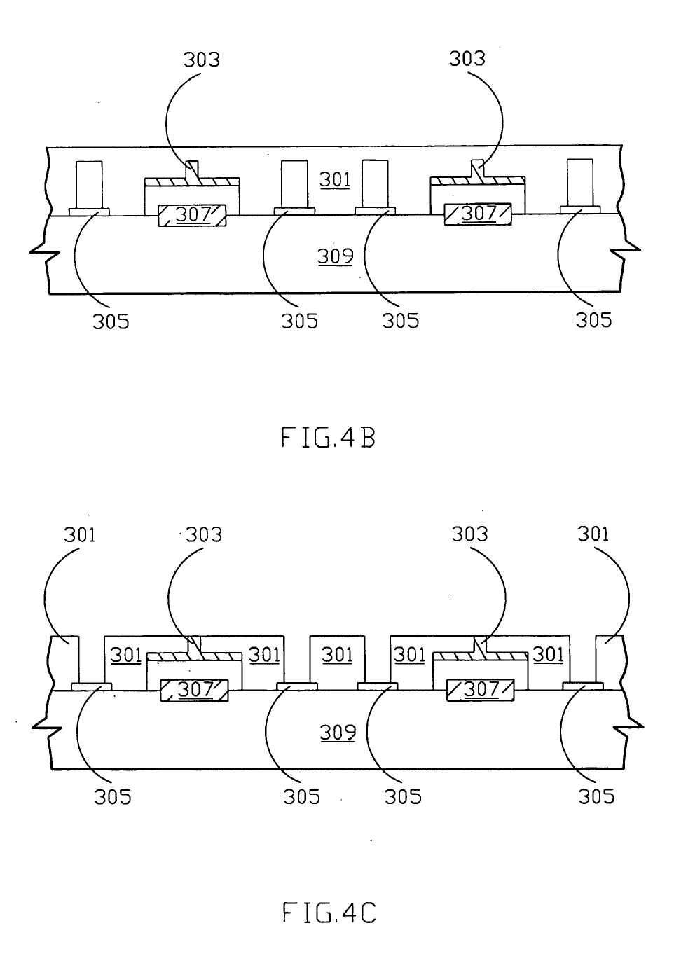

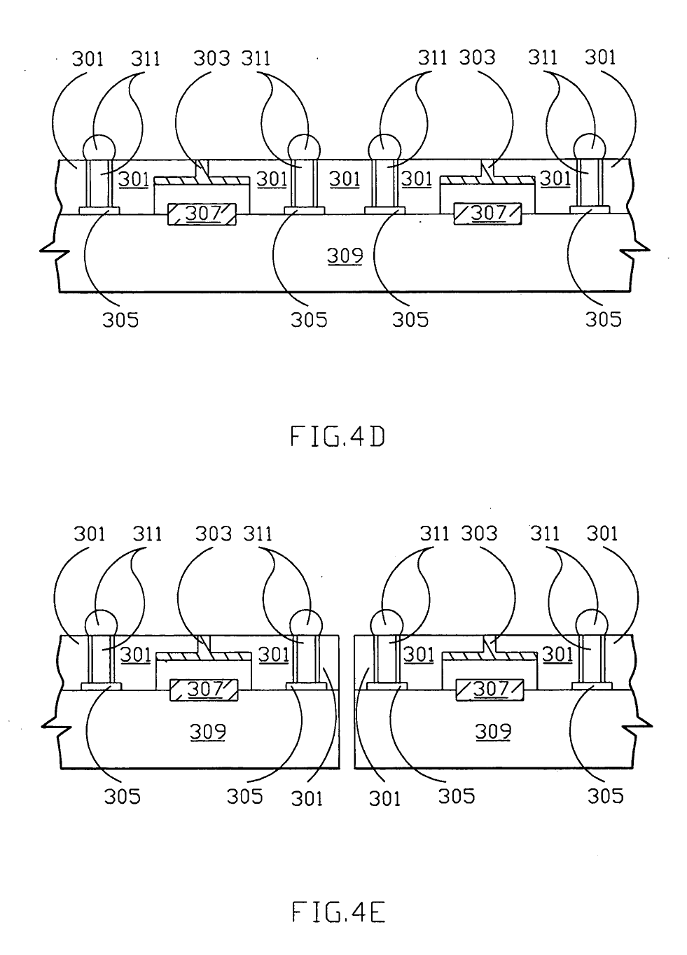

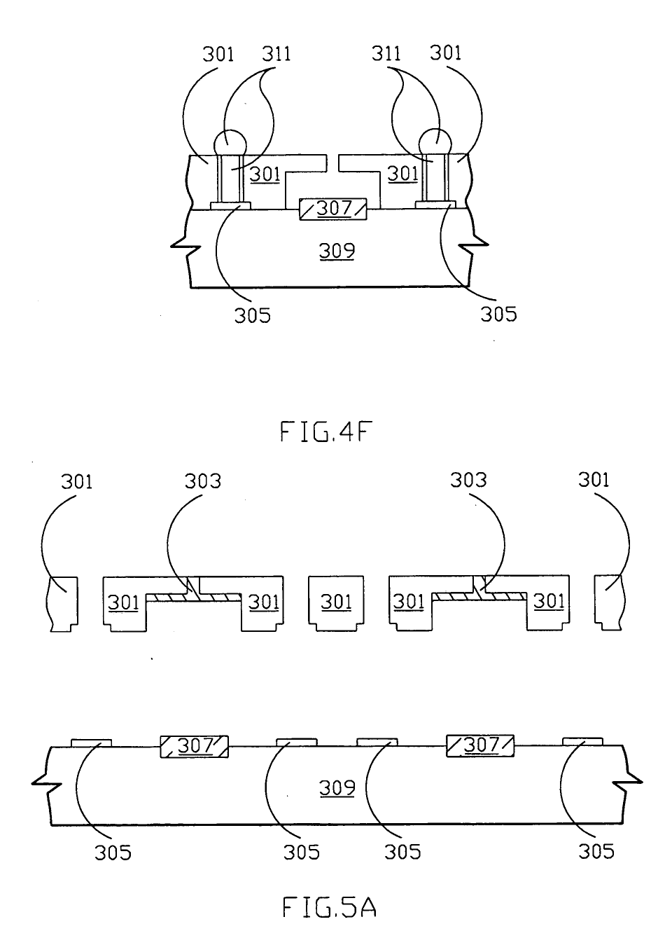

Next, referring to FIG. 4A˜FIG. 4F, the diagrams depict the wafer level package process harmony with the flip-chip package according to another embodiment of the present invention. The steps of the fabricating process in the embodiment includes, aligning the substrate 309 and the lid substrate 301 (as shown in FIG. 4A), where the lid substrate 301 is formed by a thermoforming method, an etching method and an EMC method, and the lid substrate 301 has several notches and openings filled with a protective gel 303; bonding the lid substrate 301 to the substrate 309 (as shown in FIG. 4B), thus there is a cavity (toward to the elements 307) on the lid substrate is formed. Then, by using a lapping process (such as an etching method, a grinding method and a polishing method), lapping the lid substrate 301 (as shown in FIG. 4C) and revealing the protective gel 303 and the pads 305. And then, forming solder bumps 311 on the several pads 305 (as shown in FIG. 4D). Next, a dicing step is performed for making each of the elements 307 of the substrate 309 diced on a single chip. Since the notches and the openings are closed by the protective gel 303, thus cuttings and trimmings will not be in contact with the elements during the lapping process, as shown in FIG. 4E. And next, removing the protective gel 303 by an appropriate method and then making the elements become in contact with the atmosphere (for instance, by using organic solution or reactive gas), which is as shown in FIG. 4F.

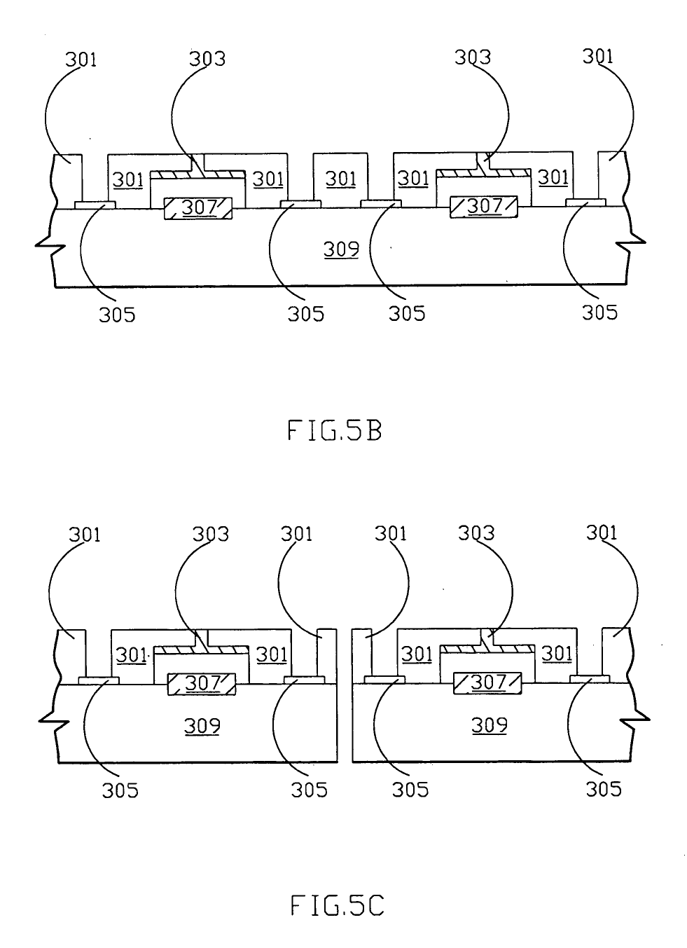

In the above-mentioned embodiments, the lapping process is performed after the bonding of the lid substrate and the substrate is finished; however, it is not restricted in the embodiments of the present invention. FIG. 5A˜FIG. 5D are the diagrams illustrating the wafer level package process according to still another embodiment of the present invention. The difference between the package process of FIGS. 5A˜5D and FIGS. 3A˜3F is that, the lid substrate in FIGS. 5A˜5D performs a lapping process after the lid substrate is finished for revealing the protective gel 303 (as shown in FIG. 5A. Then, bonding the lid substrate 301 to a substrate 309, which is as shown in FIG. 5B. When the wafer level package is designed for being connected by a wire-bonding method, a dicing step is performed for making each of the elements 307 of the substrate 309 are diced in a single chip, which is as shown in FIG. 5C. Next, removing the protective gel 303 by an appropriate method and then making the elements become in contact with the atmosphere (for instance, by using organic solution or reactive gas), thus a package structure is finished (which is similar as shown in FIG. 3E). When the material of the substrate 309 or the material of the lid substrate 301 is selected from the material, except the silicon wafer (or glass), it is needed as a dispensing process for dispensing the upper edge of the lid substrate 301 with an adhesive 310 and combining of the substrate 309 with the lid substrate 301. Further, when the wafer level package is designed for being connected by the flip-chip package, by using the solder bump implantation method of general flip-chip package: removing the protective gel 303 by an appropriate method (for instance, by using organic solution or reactive gas) before a reflow process, performing a reflow step for making the solder bumps 311 to be spherical-shaped solder bumps. Finally, making the pads 305 of the elements 307 to be connected the external circuit and thus a finished package structure is obtained as shown in FIG. 5D.

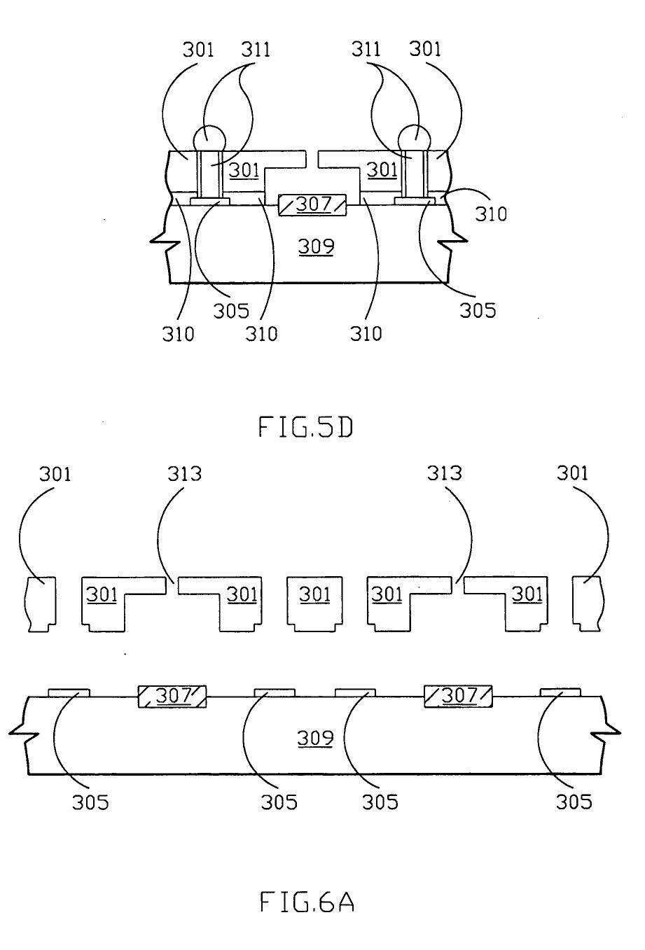

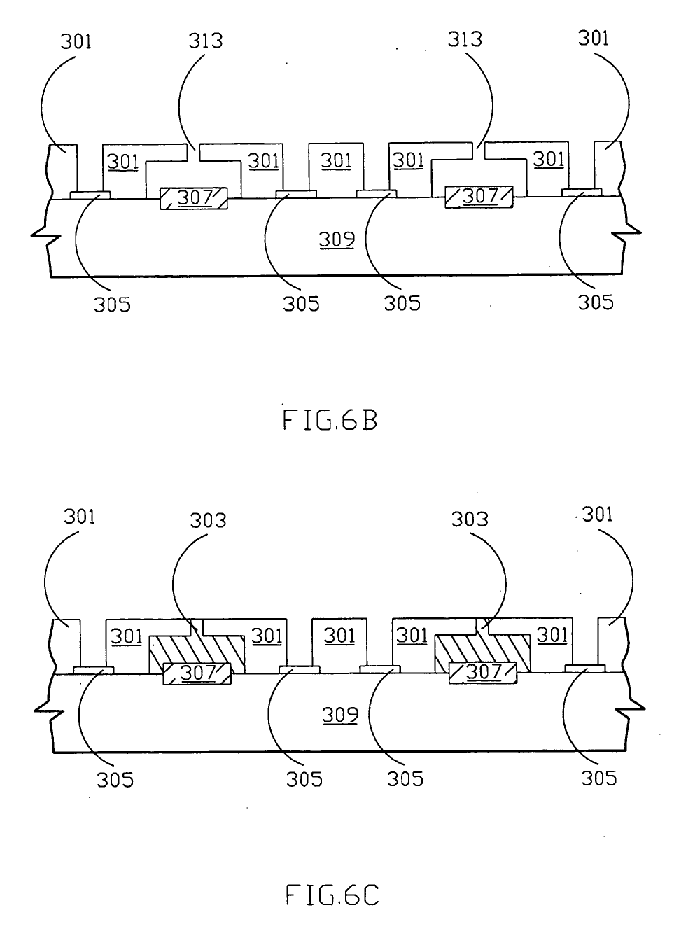

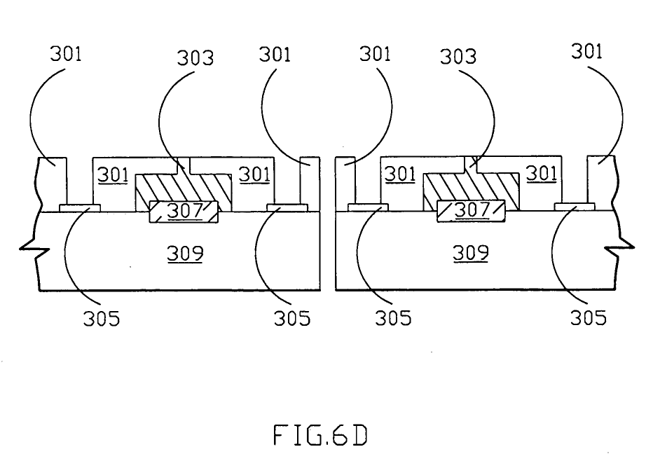

In the following, referring to FIG. 6A˜FIG. 6D, the diagrams depict the wafer level package process according to still another embodiment of the present invention. The difference between the package process of FIGS. 5A˜5D and FIGS. 6A˜6D is that the lid substrate 301 in FIGS. 6A˜6D is formed by the thermoforming method, the etching method and the EMC (epoxy molding compound) method, and then a lapping process is performed for making the openings 313; however, there is no protective gel filled in that. The steps in the fabricating process of the embodiment includes, aligning the substrate 309 and the lid substrate 301 (as shown in FIG. 6A), where the lid substrate 301 is formed by a thermoforming method, an etching method and an EMC method, and the lid substrate 301 has several notches and penetrating openings formed by a lapping process; bonding the lid substrate 301 to the substrate 309 (as shown in FIG. 6B). Then, by using the screen printing method to fill the penetrating openings 313 with a protective gel 303; thus the notches and the openings is filled with the protective gel 303 and the openings are closed, as is shown in FIG. 6C. When the wafer level package is designed for being connected by a wire-bonding method, a dicing step is performed for making each of the elements 307 of the substrate 309 diced on a single chip, which is as shown in FIG. 5C. Next, removing the protective gel 303 by an appropriate method and then making the elements contacted with the atmosphere (for instance, by using organic solution or reactive gas), thus a package structure is finished (which is similar as shown in FIG. 3E). When the material of the substrate 309 or the material of the lid substrate 301 is selected from the material, except a silicon wafer (or glass), it is needed as a dispensing process for dispensing the upper edge of the lid substrate 301 with an adhesive 310 and combining of the substrate 309 with the lid substrate 301. Further, when the wafer level package is designed for being connected by flip-chip package, by using the solder bump implantation method of general flip-chip package: removing the protective gel 303 by an appropriate method (for instance, by using organic solution or reactive gas) before a reflow process, performing a reflow step for making the solder bumps 311 to be spherical-shaped. Finally, making the pads 305 of the elements 307 to be connected to the external circuit and thus a finished package structure is obtained as shown in FIG. 5D.

Similarly, during the bonding process of the embodiments of FIGS. 4A˜4F, FIGS. 5A˜5D and FIGS. 6A˜6D, bonding method of that has different ways in accordance with the materials of the substrate 309 and the lid substrate 301. When the material of the substrate 309 or the material of the lid substrate 301 is selected from the material except silicon wafer (or glass), it is needed a dispensing process for dispensing the upper edge of the lid substrate 301 with an adhesive 310 and combining of the substrate 309 with the lid substrate 301. The substrate and lid substrate can be combined by anodic bonding when the material of the substrate is silicon wafer and the material of the lid substrate is glass or when the material of the substrate is glass and the material of the lid substrate is silicon wafer.

While this invention has been described with reference to illustrative embodiments, this description does not intend or construe in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. Wafer level package apparatus, comprising:
a substrate, wherein said substrate has a plurality of elements and a plurality of pads corresponding to said elements; and
a lid substrate configured to combined with said substrate, wherein said lid substrate has at least one opening and a plurality of notches, and said at least one opening and said plurality of notches are corresponding to said plurality of elements fabricated on said substrate and thus form said wafer level package apparatus after said combination of said substrate and said lid substrate is finished.

2. The apparatus according to claim 1, wherein the material of said substrate is selected from the group consisting of ceramics, high polymeric aminates, silicon wafer, glass, compounds and plastics.

3. The apparatus according to claim 1, wherein forming said lid substrate is selected from the method consisting of a thermoforming method, an etching method and an EMC (epoxy molding compound) method.

4. The apparatus according to claim 3, wherein the material of said lid substrate is selected from the group consisting of thermoplastic polyester, polycarbonate (PET) and PC when using said thermoforming method to form said at least one opening and said plurality of notches on said lid substrate.

5. The apparatus according to claim 3, wherein the material of said lid substrate is selected from the group consisting of silicon wafer and glass when using said etching method to form said at least one opening and said plurality of notches on said lid substrate.

6. The apparatus according to claim 3, wherein the material of said lid substrate is epoxy when using said EMC method to form said at least one opening and said plurality of notches on said lid substrate.

7. The apparatus according to claim 1, wherein said plurality of elements ate selected from the group consisting of micro inertial sensors, micro pressure gauge, micro hygrometer and micro gas sensors.

8. A wafer level package method, comprising:
providing a substrate, wherein said substrate has a plurality of elements and a plurality of pads corresponding to said plurality of elements;
providing a lid substrate, wherein said lid substrate has a plurality of openings and a plurality of notches, and said plurality of openings and said plurality of notches are corresponding to said plurality of elements fabricated on said substrate;
aligning said substrate and said lid substrate for aligning said plurality of elements of said substrate with said corresponding plurality of openings and said corresponding plurality of notches, and thus forming wafer level package apparatus by using a bonding process; and
dicing said combined apparatus composed of said substrate and said lid substrate for forming a plurality of chips.

9. The method according to claim 8, further comprising:
wire-bonding said pads after the step of dicing said combined apparatus.

10. The method according to claim 8, further comprising:
forming a plurality of solder bumps on said plurality of pads before the step of dicing said combined apparatus.

11. The method according to claim 8, wherein the material of said substrate is selected from the group consisting of ceramics, high polymeric aminates, silicon wafer, glass, compounds and plastics.

12. The method according to claim 8, wherein forming said lid substrate is selected from the method consisting of a thermoforming method, an etching method and an EMC (epoxy molding compound) method.

13. The method according to claim 12, wherein the material of said lid substrate is selected from the group consisting of thermoplastic polyester, polycarbonate (PET) and PC when using said thermoforming method to form said at least one opening and said plurality of notches on said lid substrate.

14. The method according to claim 12, wherein the material of said lid substrate is selected from the group consisting of silicon wafer and glass when using said etching method to form said at least one opening and said plurality of notches on said lid substrate.

15. The method according to claim 12, wherein the material of said lid substrate is epoxy when using said EMC method to form said at least one opening and said plurality of notches on said lid substrate.

16. The method according to claim 8, wherein said substrate and said lid substrate are combined by anodic bonding method when the material of said substrate is silicon wafer and the material of said lid substrate is glass.

17. The method according to claim 8, wherein said substrate and said lid substrate are combined by anodic bonding method when the material of said substrate is a glass and the material of said lid substrate is silicon wafer.

18. The method according to claim 11, further comprising:
dispensing the upper edge of said lid substrate with adhesive when the material of said substrate is selected from the group consisting of said ceramics, said high polymeric aminates, said compounds and said plastics.

19. The method according to claim 12, further comprising:
filling said plurality of notches with a protective gel for closing said plurality of openings.

20. The method according to claim 19, wherein said protective gel is selected from the group consisting of photoresist, polyimide and benzocyclobutene (BCB).

21. The method according to claim 8, further comprising:
filling said plurality of notches with a protective gel for closing said plurality of openings after bonding of said substrate and said lid substrate is finished.

22. The method according to claim 21, wherein the step of filling said plurality of notches with a protective gel is formed by dispensing or screen printing.

23. The method according to claim 12, further comprising:
lapping said lid substrate when said lid substrate is formed by said thermoforming method or said EMC (epoxy molding compound) method.

24. The method according to claim 23, wherein the step of lapping said lid substrate is performed after said lid substrate is formed.

25. The method according to claim 23, wherein the step of lapping said lid substrate is performed after said wafer level package apparatus is formed.

26. The method according to claim 19, further comprising
removing said protective gel after said plurality of chips are formed by dicing.

27. The method according to claim 21, further comprising:
removing said protective gel after said plurality of chips are formed by dicing.

28. The method according to claim 8, wherein said plurality of elements are selected from the group consisting of micro inertial sensors, micro pressure gauge, micro hygrometer and micro gas sensors.
